(19) United States
(12) Patent Application Publication
(10) Pub. No.: US 2025/0253815 A1
(43) Pub. Date: Aug. 7, 2025

(54) HIGH-VOLTAGE HIGH-TRANSCONDUCTANCE AMPLIFIER FOR COMPARATOR INPUT STAGE

(71) Applicant: Analog Devices, Inc., Wilmington, MA (US)

(72) Inventor: Christopher C. McQuilkin, Hollis, NH (US)

(21) Appl. No.: 18/434,520

(22) Filed: Feb. 6, 2024

(51) Int. Cl. H03F 3/45; H03F 1/08; H03G 1/00; H03K 17/30

(52) U.S. Cl. CPC H03F 3/45183; H03F 1/086; H03G 1/0029; H03K 17/302; H03F 2200/219; H03F 2200/261; H03F 2200/462

(57) ABSTRACT

A gain stage circuit can include first and second follower circuits arranged as a differential pair and configured to receive respective input signals. The gain stage circuit can include or use a pass stage circuit including an adjustable-impedance signal path that couples the first and second follower circuits. The gain stage circuit can further include or use a control circuit to receive the input signals and, in response, provide a control signal to the pass stage circuit to control an impedance of the signal path that couples the first and second follower circuits.

### BACKGROUND

A test system for electronic device testing can include a pin driver circuit that provides a voltage test pulse to a device under test (DUT). In response, the test system can be configured to measure a response from a DUT, such as to determine whether the DUT meets one or more specified operating parameters. A test system can optionally include multiple driver circuits, such as a class AB driver circuit and a class A driver circuit to provide circuit test signals having different amplitude or timing characteristics. In an example, the test system is configured to measure a response from a DUT using a comparator circuit to sense transitions at a DUT pin.

A system for testing digital integrated circuits (ICs) can include a driver circuit configured to provide multiple voltage levels (e.g., Vhigh, Vlow and Vterm) to a DUT. The DUT can exhibit bidirectional (I/O) capability in that it can both source and receive stimulus. The driver circuit's Vhigh and Vlow levels serve to stimulate a DUT while in its “input” state, and Vterm acts as a termination for the DUT in its “output” state. The process of switching between Vhigh, Vlow, and Vterm can be conceptualized as a collection of three switches, with one terminal of each switch connected to either Vhigh, Vlow, or Vterm, and the other terminal connected to a 50 ohm resistor, which is then connected to the DUT node. Transitions between the three levels can be realized by opening and closing the appropriate switches, such as with only one switch closed at any given time.

In an example, a test system includes an amplifier or comparator comprising a transconductance circuit (also referred to as a “transconductor” or a “voltage-to-current converter”). A transconductance circuit is a circuit that generates an output current corresponding to, or proportional to, an input voltage. Accordingly, such circuits may be referred to as voltage-to-current converters.

Various comparator circuit structures have been proposed. Some have enhanced latching accuracy or enhanced bandwidth capabilities for operations such as high-speed sampling in applications including analog-to-digital converters or automated test equipment (ATE). In an example, a comparator circuit includes an AC input node, a DC input node, and an output node. In an example that includes a comparator in a circuit configured to execute automated testing of a DUT, the AC input node can be coupled to a DUT interface node, and the DC input node can be coupled to a reference node to receive a reference voltage signal. Signal changes at the output node of the comparator circuit can provide information about a relationship between the DUT output and the reference voltage signal.

### BRIEF SUMMARY

The present inventor has recognized that a problem to be solved includes providing a gain stage that has high gain, large differential voltage compliance and high bandwidth characteristics. The gain stage can optionally be used in a comparator or other automated test equipment.

In an example, a solution can include or use a system comprising a transconductance circuit with degeneration transistors. In some examples, a transconductance circuit with degeneration transistors can be used as a transconductance input stage of an amplification stage, where the transconductance input stage is configured to convert an input voltage signal to an output current signal. In some examples, the amplification stage may further include a load stage, configured to convert the input stage output current back to an output voltage. One or more of such amplification stages may be included in a device such as an amplifier or a comparator.

In an example, a transconductance stage can include a first follower circuit coupled to a first input node, a second follower circuit coupled to a second input node, and a pass stage circuit that provides an adjustable-impedance signal path that couples the first and second follower circuit. The transconductance stage can further include or use a control circuit configured to receive a first input signal from the first input node and a second input signal from the second input node and, in response, provide a control signal to the pass stage circuit to control an impedance of the signal path that couples the first and second follower circuits.

This summary is not intended to provide an exclusive or exhaustive explanation of the invention. The detailed description is included to provide further information about the present patent application.

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

FIG. 1 illustrates generally an example of a first test system that includes a pin driver.

FIG. 2 illustrates generally an example of a multiple-stage comparator circuit.

FIG. 3 illustrates generally an example of a first transconductance circuit.

FIG. 4 illustrates generally an example of a second transconductance circuit.

FIG. 5 illustrates generally an example of a third transconductance circuit.

FIG. 6 illustrates generally an example of a gate drive circuit.

FIG. 7 illustrates generally an example of a method for controlling gain and bandwidth characteristics of a gain stage circuit.

### DETAILED DESCRIPTION

An automated test equipment (ATE) pin electronics integrated circuit of a test system can provide a voltage pulse stimulus to a device under test (DUT) at a specified time using a pin driver, and optionally can measure a response signal from the DUT using a comparator. The test system can be configured to provide high fidelity output signal pulses over a relatively large output signal magnitude range to accommodate different tests and different types of devices under test.

In an example, a test system can include a pin driver architecture that can provide high fidelity stimulus signals with minimal overshoot or spiking of high frequency signals, and can enhance pulse edge placement accuracy and signal bandwidth at high or low power operating levels. In an example, a test system can include one or more driver stages, such as can include a class A driver stage or a class AB driver stage, such as can be configured to provide a variety of pulse signals. The systems can include control circuits to precisely adjust switching voltage signals and switching current signals, and to control an operating mode and monitoring or measuring activity of a comparator.

In an example, multiple drivers or driver stages can be used to provide a test system that is configurable to test a variety of semiconductor devices with varying voltage and speed requirements. Furthermore, multiple drivers can be used to enhance or enable multiple signal level testing or “multiplexing” for physical layer testing. During physical layer testing, the multiple drivers can be switched concurrently to provide various stimuli or drive signals to a DUT.

In an example, a pin driver stage of a test system comprises a portion of the interface between the tester and the DUT. The pin driver stage can be responsible for establishing the timing accuracy of the test system. That is, the pin driver stage can be configured to precisely deliver DUT stimulus signal edges substantially independently of environmental or other factors. In some examples, the pin driver stage is configured to support higher frequency, lower voltage current stimulus signals, and lower frequency, higher voltage stimulus signals. In an example, the pin driver stage maintains a particular characteristic impedance (e.g., 50 ohms) that is optimized for bandwidth and timing accuracy. The characteristic impedance can be matched to, for example, an impedance of a transmission line that couples the test system to the DUT.

A test system can include a comparator circuit or comparator stage that is configured to receive high speed, high voltage response signals from a DUT. A comparator, generally, is a decision element that provides information about a relationship between at least two input signals. For example, a comparator can provide a digital output (e.g., a logic high or a logic low signal) that indicates a relationship between a signal from a DUT and a reference signal, such as a reference voltage signal. The comparator can include one or more gain stages, such as can be coupled in series, to yield a high gain response.

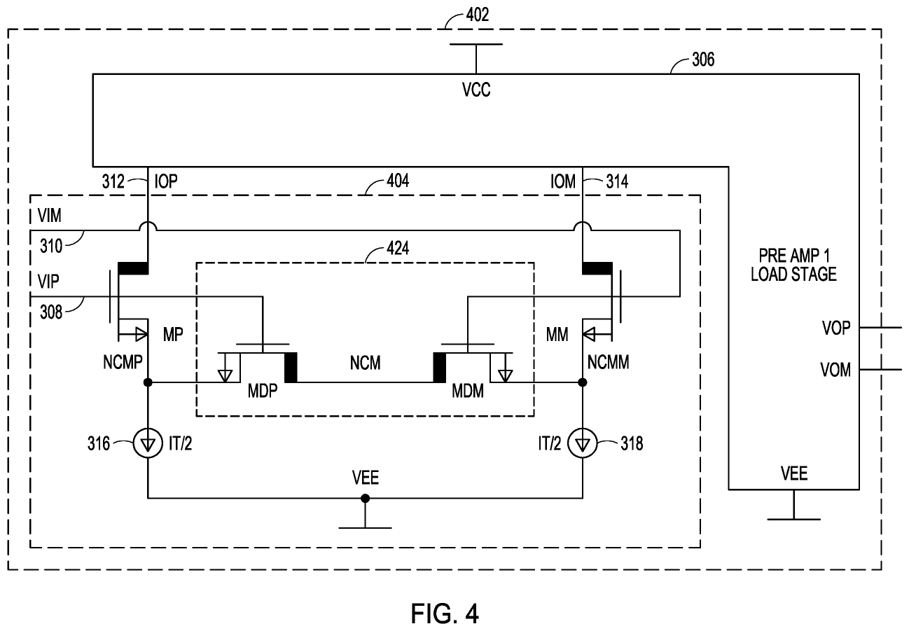

The present inventor has recognized that a problem to be solved includes providing a gain stage that has high gain, large differential voltage compliance and high bandwidth characteristics. The problem includes providing a differential gain stage that has high tolerance for large Common Mode (CM) and Differential Mode (DM) input voltages. The present inventor has recognized that an issue with a standard differential pair gain stage, such as can use DMOS devices (e.g., double-diffused MOSFET devices), is that while a differential pair can handle a large CM range, the gain stage can be limited by a relatively low (e.g., 5V) Vgs (gate-source voltage) limit, beyond which device damage can occur. This limitation means that while a DMOS device can tolerate high Vdg (drain-gate voltage), the Vgs tolerance is low, resulting in a circuit that can handle high CM voltages but has a very small DM voltage tolerance. Furthermore, the present inventor has recognized that using high voltage diodes at the tail node (e.g., provided in series with the sources of the DMOS devices that comprise a differential pair) to improve CM tolerance is not always available because not all processes offer high voltage diodes. Other solutions that employ transistors at the tail node (e.g., in series with the differential pair device sources; see FIG. 4) to achieve high CM and DM voltage tolerance can result in low gain and low bandwidth. Specifically, in the transistor-based approach, achieving high gain requires the use of physically large transistors, which in turn capacitively loads the positive and negative inputs and reduces the bandwidth of the gain stage, and achieving high bandwidth requires physically small transistors which reduces the gain. The present inventor has recognized that a solution to these problems and limitations can include or use gate drive circuits to control the transistors at the tail node. By controlling operation of these transistors, CM and DM voltage tolerance is improved, and high gain and high bandwidth can be achieved.

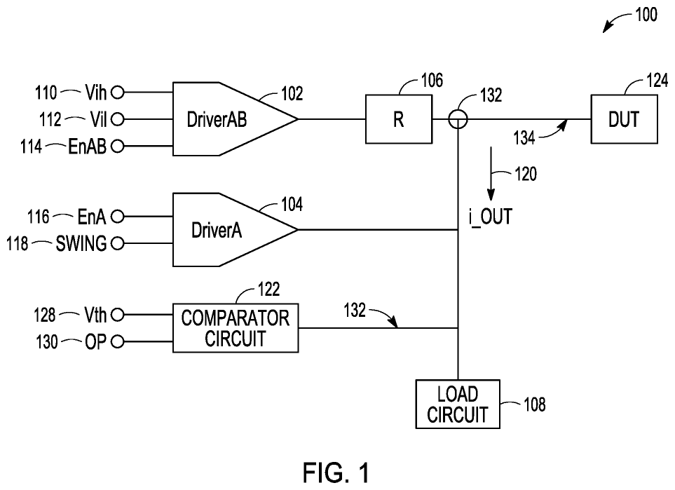

FIG. 1 illustrates generally a first example test system 100 showing a test system topology that includes multiple driver stages, a load, and a comparator stage. The first example test system 100 includes a driver system comprising a first DriverAB 102 that can include a class AB driver circuit, and a first DriverA 104 that can include a class A driver circuit. The first example test system 100 can further include an output element such as a first resistor 106 that can be configured to provide a specified output or load impedance. In an example, the first example test system 100 includes a comparator circuit 122, or a first load circuit 108, such as can include an active load or other loading device. In an example, the test system is configured to provide a first output current 120, i_OUT, at a DUT interface or DUT node 132. The DUT node 132 can be coupled to a DUT 124 using a loaded signal path 134. In some examples, the first resistor 106 and the loaded signal path 134 have matching impedance characteristics.

In an example, the first DriverAB 102 can be configured to produce a voltage stimulus signal by selecting between parallel-connected diode bridges with each bridge driven by a unique, dedicated DC voltage level. In the first example test system 100 of FIG. 1, DC voltages Vih 110 and Vil 112 drive diode bridges in the first DriverAB 102. The switching stage can be followed by a voltage buffering stage that can provide power gain, such as can be used to produce large currents to serve a 50 ohm DUT environment.

In contrast with the first DriverAB 102, the first DriverA 104 can be configured to produce transitions at the DUT node 132 using a relatively large current switch stage that can be coupled directly to the DUT node 132. A current switching stage in the first DriverA 104 can alternately switch current into and out of the DUT node 132 in response to a control signal Swing 118, such as can be a voltage control signal. The first DriverA 104 can provide high speed operation, for example, because it may be unburdened by the class AB voltage buffering stage with its attendant bandwidth limitations and other performance limitations.

In an example, the first DriverA 104 can be configured to provide a relatively low amplitude signal at the DUT node 132. For example, the first DriverA 104 can provide a signal having about a 2 volt swing. The first DriverAB 102 can be configured to provide a relatively high amplitude signal at the DUT node 132, for example, −1.5 to +7 volts. The first DriverA 104 generally operates at a higher switching speed or bandwidth than the first DriverAB 102. In an example, the first DriverAB 102 can be configured to absorb switching currents from the first DriverA 104. That is, the first DriverAB 102 can serve as a buffer that the first DriverA 104 can source current into, such as through the first resistor 106.

One or both of the first DriverAB 102 and the first DriverA 104 can be selected to fulfill disparate DUT test requirements that may not otherwise be fulfilled by a single driver. For example, while both driver circuits can provide DUT waveforms, the first DriverAB 102 can be configured to provide larger amplitude, lower bandwidth stimulus signals, and the first DriverA 104 can be configured to provide lower amplitude, higher bandwidth stimulus signals. In other examples, a single driver (e.g., the first DriverAB 102) can be used.

In an example, the first DriverAB 102 and the first DriverA 104 do not share an enable pin. Instead, each driver circuit includes an independent enable control through pins EnAB 114 and EnA 116. The independent enable control facilitates the first DriverAB 102 to serve as a low speed, high voltage stimulus source, and to serve as a static, non-transitioning buffer to absorb switching currents from the first DriverA 104.

FIG. 1 includes the comparator circuit 122. The comparator circuit 122 can include a single-stage or multiple-stage comparator that is configured to receive a signal from the DUT 124, such as via the DUT node 132 and the loaded signal path 134. The comparator circuit 122 can compare the received signals to a comparator reference signal 128 (e.g., Vth) and, in response, provide a differential comparator output signal 130 (e.g., OP). For example, the comparator circuit 122 can receive a voltage response signal from the DUT 124 and compare an amplitude of the voltage response signal to an amplitude of the comparator reference signal 128. The comparator circuit 122 can provide information about the amplitude relationship using the differential comparator output signal 130, such as can include a digital signal or logic output signal.

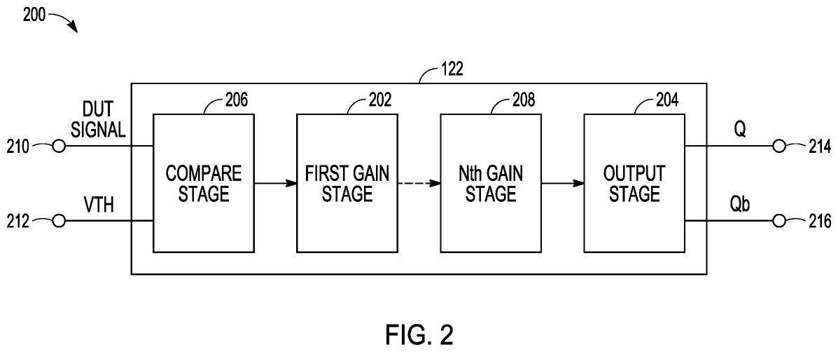

FIG. 2 illustrates generally a comparator example 200 that can include the comparator circuit 122. The comparator circuit 122 can include a comparator input node 210, a reference signal input node 212, a first output node 214, and a second output node 216. The comparator circuit 122 can include multiple different circuit stages provided in series. For example, the comparator circuit 122 can include a compare stage 206, one or more gain stages, such as a first gain stage 202 through an nth gain stage 208, and an output stage 204.

In an example, the compare stage 206 can be configured to receive information from the DUT node 132 from the DUT 124, such as via the loaded signal path 134, using the comparator input node 210. The compare stage 206 can receive the comparator reference signal 128 Vth using the reference signal input node 212. Generally, the compare stage 206 is configured to perform a signal comparison operation to determine which of the respective signals at the comparator input node 210 and the reference signal input node 212 has a greater or lesser signal amplitude characteristic, such as at a particular or specified time. A comparison result or output of the compare stage 206 can be provided to the first gain stage 202. In an example, the comparison result includes a differential signal or logic signal, that is, a signal having two signal components.

In an example, the compare stage 206 includes a differential amplifier that amplifies a differential voltage received at the comparator input node 210 and the reference signal input node 212, and suppresses common-mode signal components. Various other compare stage 206 circuits can be used, such as including one or more of the comparators described by McQuilkin in U.S. Pat. No. 9,813,050, titled “Comparator Circuit with Input Attenuator.” The compare stage 206 decision circuit can include, among other things, a differential pair that reports when the DUT signal crosses the reference signal voltage Vth, but can also serve as a level shifter to allow the subsequent gain stages to operate below ground, such as to save power.

The first gain stage 202 can include various gain or amplifier circuitry. That is, the first gain stage 202 can include amplifier circuitry such as can include operational amplifiers or other arrangements or configurations of transistors or other circuitry to perform signal amplification or buffering. Multiple gain stage instances can be provided in series, such that each gain stage further amplifies or buffers an output of a preceding gain stage. In the example of FIG. 2, the first gain stage 202 provides a first gain stage output signal to one or more intermediate gain stages that, in turn, provide a gain stage output using a last or nth gain stage 208. The nth gain stage 208 can be configured to provide an output signal into a relatively high input impedance receiver in the output stage 204. In response, the output stage 204 can provide an output signal to a low impedance environment. The various gain stages, such as the first gain stage 202, the nth gain stage 208, and any one or more intervening gain stages, can be identically or differently configured.

In an example, the output stage 204 provides the differential comparator output signal 130 that includes first and second signal components Q and Qb at the first output node 214 and second output node 216, respectively. That is, the comparator stage output signal components can be used to provide a digital output signal indicative of a magnitude relationship between the input signals received at the comparator input node 210 and the reference signal input node 212.

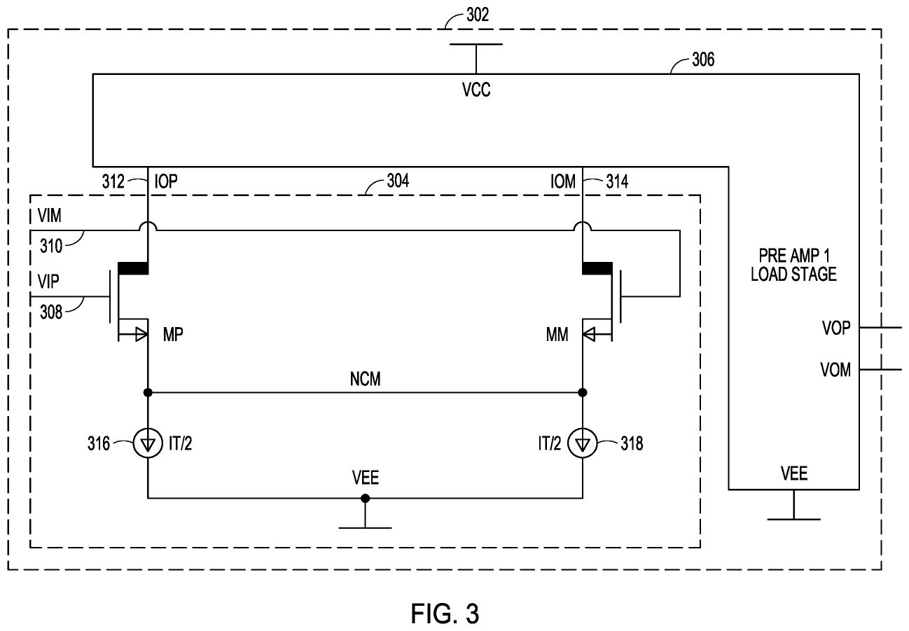

FIG. 3 illustrates generally an example of first amplification stage 302. The first amplification stage 302 can include a first transconductance circuit 304 with multiple follower circuits. In the example of FIG. 3, the first transconductance circuit 304 includes a pair of source-follower circuits arranged as a differential pair. In an example, the first amplification stage 302 comprises a comparator or an amplifier, such as can include the compare stage 206 of the comparator example 200 of FIG. 2. The first amplification stage 302 can be a first preamplifier stage and may be followed up by one or more other gain stages. In the example of FIG. 3, the first amplification stage 302 can include a load circuit 306, which in turn can provide an output to a subsequent gain stage or output stage.

The example of FIG. 3 shows a first input transistor MP comprising a portion of a first follower circuit and a second input transistor MM comprising a portion of a second follower circuit. In an example, the input transistors MP and MM comprise a differential pair circuit. Each of the input transistors MP and MM can include a respective high-voltage transistor (e.g., an LDMOS transistor). A common-mode voltage range of the differential pair can be equal to the LDMOS drain-source (DS) breakdown voltage (BV), or BVDS (e.g., 24 V or more). The differential input voltage range, however, can be approximately equal to a gate-to-source breakdown voltage plus a gate-to-source voltage, or VGS (e.g., 6 V).

In the first transconductance circuit 304, one terminal of the first input transistor MP (e.g., the gate terminal of the transistor MP) is coupled to a first input 308 and the first input transistor MP receives a first input voltage VIP. One terminal of the second input transistor MM (e.g., the gate terminal of the transistor MM) is coupled to a second input 310 and the second input transistor MM receives a second input voltage VIM. A second terminal of the first input transistor MP (e.g., the drain terminal of the transistor MP) is coupled to a first output 312 to provide a first output current IOP, and a second terminal of the second input transistor MM (e.g., the drain terminal of the transistor MM) is coupled to a second output 314 to provide a second output current IOM. A third terminal of the first input transistor MP (e.g., the source terminal of the transistor MP) is coupled to a third terminal of the second input transistor MM (e.g., the source terminal of the transistor MM), e.g., via an intermediate node NCM. For each of transistors MP and MM, the source terminal of the transistor can be coupled to the back gate terminal of the transistor.

In an example, the first transconductance circuit 304 can include a first current source 316 and a second current source 318. The first current source 316 can be coupled to the source terminal of the first input transistor MP, and the second current source 318 can be coupled to the source terminal of the second input transistor MM. Together, the first current source 316 and the second current source 318 provide a total tail current IT for the differential pair of the input transistors MP and MM of the first transconductance circuit 304. In an example, each of the first current source 316 and the second current source 318 provides a tail current IT/2.

In some examples, the first transconductance circuit 304 comprises a portion of a comparator circuit, such as can be included in the comparator example 200. In this case, VIP and VIM can be the inputs to the comparator. The inputs can be provided or driven by an outside source, such as a DUT. The first transconductance circuit 304 can thus be configured to evaluate a difference between the voltage levels of the inputs VIP and VIM and generate an output current that represents whether the difference is positive or negative (e.g., to generate a logic 1 or logic 0 output indicative of whether the difference between the voltage levels of the inputs VIP and VIM is positive or negative). For example, when the difference IOP-IOM is positive then the difference VIP-VIM is positive, and when the difference IOP-IOM is negative then the difference VIP-VIM is negative. A magnitude of the difference between IOP and IOM can be a function of the magnitude difference between VIP and VIM.

In an example, the first transconductance circuit 304 comprises an amplifier, such as can be used in a feedback circuit. Such an example of the first transconductance circuit 304 can be configured to make the inputs VIP and VIM substantially equal by changing the outputs IOP and IOM, which outputs may then be coupled to the amplifier input through a feedback path.

A problem with the first transconductance circuit 304 may arise because the voltage at the NCM node is set by the one of the input transistors MP and MM that has the largest input voltage at its gate. When the differential pair of the input transistors MP and MM completely switches the tail current IT to a particular one of the first output 312 and the second output 314, the turned-off input transistor (i.e., the one of the input transistors MP and MM that has the lowest input signal at its gate terminal) can experience a gate breakdown at its source terminal boundary. For example, when the first transconductance circuit 304 is used in a comparator (e.g., a high-voltage comparator), the minimum and maximum levels of difference between VIP and VIM can exceed the gate oxide reliability voltage rating of the input transistors MP and MM. When the first transconductance circuit 304 is used in an amplifier, and if the amplifier input signal range is larger than the breakdown ratings of the input transistors MP and MM, then the amplifier may have the same reliability problem as a high-voltage comparator. During steady-state, such as when the amplifier settles to its final output level or waveform, the two inputs VIP and VIM would be substantially equal and would not have a reliability problem, but the inputs VIP and VIM can be significantly different at the beginning of the settling, which can create reliability issues for the amplifier. Hence, the differential pair-based first transconductance circuit 304 can be insufficient or unreliable for high-voltage applications.

FIG. 4 illustrates generally an example of a second transconductance circuit 404 with a differential pair included in a second amplification stage 402. In an example, the second amplification stage 402 comprises a comparator or an amplifier, such as can comprise the compare stage 206 of the comparator example 200. The second amplification stage 402 can be a first preamplifier stage and can be followed by one or more other gain stages.

The example of FIG. 4 shows the differential pair of input transistors MP and MM, such as comprising respective follower circuits, and each of the input transistors can include a high-voltage transistor (e.g., an LDMOS transistor). A common-mode voltage range of the input differential pair is equal to the LDMOS BVDS, e.g., 24 volts (V). The differential input voltage range, however, can be approximately equal to a gate-to-source breakdown voltage plus a gate-to-source voltage (VGS), e.g., about 6 V.

In the second transconductance circuit 404, as similarly provided for the first transconductance circuit 304, one terminal of the first input transistor MP (e.g., the gate terminal of the transistor MP) is coupled to the first input 308 and the first input transistor MP receives a first input voltage VIP. One terminal of the second input transistor MM (e.g., the gate terminal of the transistor MM) is coupled to the second input 310 and the second input transistor MM receives a second input voltage VIM. A second terminal of the first input transistor MP (e.g., the drain terminal of the transistor MP) is coupled to the first output 312 to provide a first output current IOP, and a second terminal of the second input transistor MM (e.g., the drain terminal of the transistor MM) is coupled to the second output 314 to provide a second output current IOM.

In contrast to the example of the first transconductance circuit 304 from FIG. 3, the second transconductance circuit 404 in FIG. 4 includes a first pass stage circuit 424. The first pass stage circuit 424 is configured to provide an adjustable-impedance signal path that couples the first and second follower circuits, or the first input transistor MP and the second input transistor MM. The first pass stage circuit 424 includes a first degeneration transistor MDP and a second degeneration transistor MDM. The first and second degeneration transistors MDP and MDM can function as nonlinear degeneration resistors.

In the example of FIG. 4, a third terminal of the first input transistor MP (e.g., the source terminal of the transistor MP) is coupled to a third terminal of the first degeneration transistor MDP (e.g., the source terminal of the first degeneration transistor MDP, which source terminal is coupled to the back gate terminal of the first degeneration transistor MDP). A third terminal of the second input transistor MM (e.g., the source terminal of the transistor MM) is coupled to a third terminal of the second degeneration transistor MDM (e.g., the source terminal of the second degeneration transistor MDM, which source terminal is coupled to the back gate terminal of the second degeneration transistor MDM). The second terminal of the first degeneration transistor MDP (e.g., the drain terminal of the first degeneration transistor MDP) is coupled to the second terminal of the second degeneration transistor MDM (e.g., the drain terminal of the second degeneration transistor MDM) at the node NCM. The first terminal of the first degeneration transistor MDP (e.g., the gate terminal of the first degeneration transistor MDP) is coupled to the first input 308 where the first degeneration transistor MDP receives the first input voltage VIP, while the first terminal of the second degeneration transistor MDM (e.g., the gate terminal of the degeneration transistor MDM) is coupled to the second input 310 and the second degeneration transistor MDM receives the second input voltage VIM.

In operation of the second transconductance circuit 404, each of the first input transistor MP and the second input transistor MM can operate in a saturation region. The first degeneration transistor MDP and the second degeneration transistor MDM may be configured to operate either in a linear (triode) region or in a saturation region. In some examples, when one of the degeneration transistors MDP and MDM enters the saturation region, the other degeneration transistor can continue to operate in the linear region.

During operation of the second transconductance circuit 404, a degeneration resistance at the source terminal of the first degeneration transistor MDP (e.g., the node NCMP shown in FIG. 4) and a degeneration resistance at the source terminal of the second degeneration transistor MDM (e.g., the node NCMM) may be symmetric with respect to the input signal difference between VIP and VIM, or AVI. That is, the resistance between the nodes NCMP and NCMM can change in accordance with changes in the applied input signal difference VIP-VIM. The value of this resistance can correspondingly change a value of the transconductance GM, where the change is symmetric in that GM (VIP-VIM)=GM (VIM-VIP). Hence, the second transconductance circuit 404 can produce the same output currents IOP and IOM if a voltage difference of 100 mV or a voltage difference of −100 m V is applied at the inputs VIP and VIM.

In an example, a total degeneration resistance between the nodes NCMP and NCMM may be smallest when the first input voltage VIP is substantially equal to the second input voltage VIM. Furthermore, the equivalent resistance between the source terminal of the first degeneration transistor MDP and the source terminal of the second degeneration transistor MDM may increase as an absolute value (or magnitude) of a difference between the input voltages VIP and VIM increases. Once the degeneration transistor whose gate terminal is coupled to the lowest input voltage (which could be either the first or second degeneration transistor MDP or MDM) enters into the saturation region, the positive and negative signal-handling portions of the second transconductance circuit 404 become effectively isolated from each other. Hence, the example input stage may not require protection devices for high-voltage protection and is self-protected.

Turning to the aspect ratios of various transistors included in the transconductance circuit, an aspect ratio (Aₓ) of a FET refers to a ratio of a channel width (wₓ) to a channel length (lₓ) of the FET. In some embodiments of a transconductance circuit, a ratio of an aspect ratio of the first degeneration transistor MDP to an aspect ratio of the first input transistor MP may be substantially equal to a ratio of an aspect ratio of the second degeneration transistor MDM to an aspect ratio of the second input transistor MM. In some embodiments, the aspect ratio of the first input transistor MP may be substantially equal to the aspect ratio of the second input transistor MM, or, equivalently, the aspect ratio of the first degeneration transistor MDP may be substantially equal to the aspect ratio of the second degeneration transistor MDM. For example, the aspect ratio of each of the first and second input transistors MP, MM may be about 1, while the aspect ratio of each of the first and second degeneration transistors MDP, MDM may be about N, where N is any positive real number. However, in other embodiments, these aspect ratios may be different, as long as the ratio of the aspect ratios of the first degeneration and input transistors MDP, MP is substantially equal to the ratio of the aspect ratios of the second degeneration and input transistors MDM, MM.

In the example of FIG. 4, the first and second degeneration transistors MDP and MDM reduce the equivalent transconductance GM of the differential pair of the first and second input transistors MP and MM. It can be shown that the equivalent transconductance GM at ΔVI=0 may be reduced by N/(1+N). Hence, the equivalent transconductance GM may drop to 80% of its value compared to the zero-degeneration case at the same power level when N=4.

When one of the first and second degeneration transistors MDP and MDM enters the saturation region, the drain current of the corresponding input transistor reaches its minimum level and is substantially equal to IT/2*(N+1). The remaining of the respective input side tail current may then be conveyed to the complementary half input side through the degeneration transistor operating in the saturation region. Under this condition, the ratio of the output currents can be substantially equal to 2N+1. If desired, these values can be arbitrarily set by properly choosing the ratio of the input and degeneration transistor aspect ratios, i.e., by choosing N.

In some examples, high small-signal gain and small input signal difference for total tail current switching goals may favor a relatively large N value, whereas reduced large signal overdrive and reduced NCMP/NCMM node capacitance-related delay variation goals may favor a relatively small N value. The exact value of N used for the transistors in the second transconductance circuit 404 can be determined, for example, using simulation. It can be shown that, in some implementations, when one of the first and second degeneration transistors MDP and MDM enters into the saturation region, the other degeneration transistor stays in the linear operation region if N is chosen larger than or equal to about 1.5. The large voltage drop between NCMP and NCMM nodes may appear mainly across the drain source terminal of the degeneration transistor operating in the saturation region.

The second transconductance circuit 404 is thus substantially symmetric with respect to the input terminals and, therefore, can process both single-ended and differential input signals. By including the first and second degeneration transistors MDP and MDM, the second transconductance circuit 404 can operate up to the BVDS of the transistors included therein without reliability problems and in absence of additional protection mechanisms.

The present inventor has recognized, however, that while the second transconductance circuit 404 provides high Common Mode and Differential Mode voltage tolerance, it exhibits relatively low gain and low bandwidth. High gain, for example, generally requires use of physically large implementations of the first and second degeneration transistors MDP and MDM, which in turn capacitively loads the first input 308 and the second input 310, respectively, and reduces bandwidth of the circuit. Conversely, high bandwidth generally requires use of physically small implementations of the first and second degeneration transistors MDP and MDM, and reduces gain of the circuit. Thus, the circuit may not simultaneously achieve high gain and high bandwidth, which is undesirable for an ideal gain stage. The present inventor has recognized that a solution to these and other problems can include or use gate drive circuits to control operation of the first and second degeneration transistors MDP and MDM, and thereby more closely approximate behavior of an ideal gain stage.

The gate drive circuits discussed herein improve the gain stage circuit and provide improvements in both Common Mode (CM) and Differential Mode (DM) voltage tolerance. These circuits achieve the improvements by, for example, actively controlling gate voltages of the pass stage transistors to maximize pass transistor Vgs. The gate drive circuits establish pass transistor Vgs at a maximum allowable voltage by a given process, minimizing pass transistor linear region impedance and thus maximizing gain. Minimizing the pass transistor linear region impedance enables the pass transistor size to be decreased, thereby increasing bandwidth while still maintaining sufficient gain. The gate drive circuits can also provide a buffering function, such as by isolating pass transistor loading effects from the input nodes. The gate drive circuits discussed herein thus help optimize circuit function by allowing bandwidth and gain manipulation while providing superior gain bandwidth product.

In an example, the gate drive circuits ensure that the pass stage transistors operate at their maximum gate-source voltage (Vgs). This is accomplished by providing an offset voltage to the gate of the pass stage transistors while preventing the Vgs from exceeding the maximum threshold that could otherwise lead to device damage.

The gate drive circuits enable the pass stage transistors to transition smoothly between the linear and saturation regions of operation based on the differential input signals. When the inputs are substantially equal, the gate drive circuits maintain the pass stage transistors in the linear region, acting as low-impedance paths and allowing for high transconductance and high bandwidth. When the inputs are not equal, the gate drive circuits cause one of the pass stage transistors to enter the saturation region, effectively becoming a current source that holds off the differential voltage across its drain-gate junction. This allows the circuit to tolerate large differential input voltages without the risk of exceeding the voltage ratings of the transistors.

By decoupling the input signals from the direct control of the pass stage transistors, the gate drive circuits also reduce capacitive loading effects, thereby providing superior gain bandwidth product relative to other solutions. This decoupling is achieved through buffering provided by the gate drive circuits, which isolates the pass stage transistors from the input signal variations and the associated capacitive effects.

In summary, the gate drive circuits provide a dual function: they establish optimal pass stage transistor Vgs characteristics while buffering the pass stage transistors from the input signals, and thereby help maximize gain and bandwidth performance. This in combination with the inherent voltage-handling benefits of DMOS devices results in a gain stage circuit with improved CM and DM voltage tolerance and improved gain bandwidth product, making it highly suitable for applications requiring robust performance across a wide range of operating conditions.

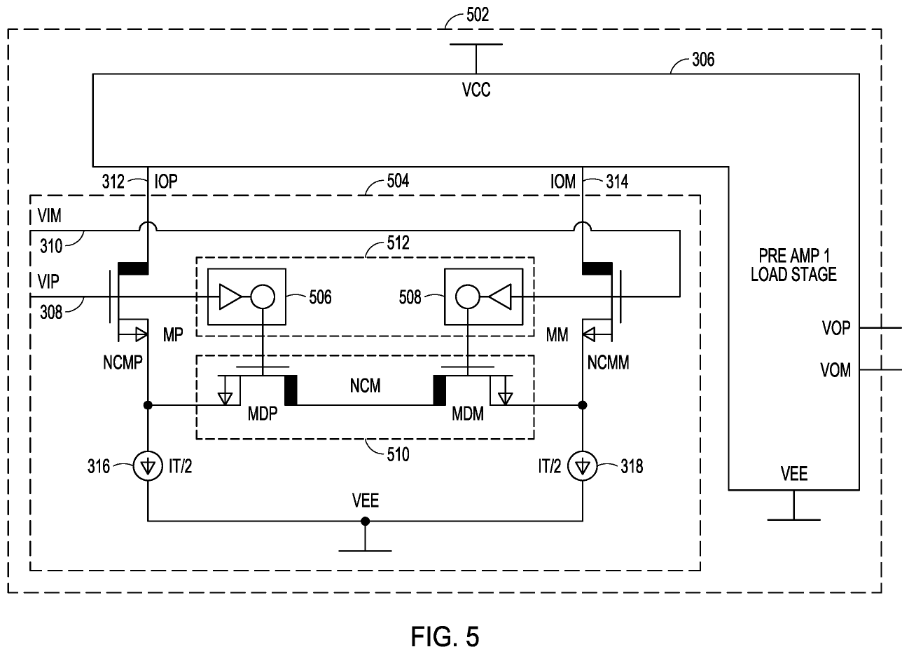

FIG. 5 illustrates generally an example of a third transconductance circuit 504 with follower circuits configured as a differential pair in a third amplification stage 502. In an example, the third amplification stage 502 comprises a comparator or an amplifier, such as can comprise the compare stage 206 of the comparator example 200. The third amplification stage 502 can be a first preamplifier stage and can be followed by one or more other gain stages.

The example of the third transconductance circuit 504 in FIG. 5 can comprise the same or similar components to the second transconductance circuit 404 from the example of FIG. 4. However, the third transconductance circuit 504 includes second pass stage circuit 510 that is configured to provide an adjustable-impedance signal path between the follower circuits. The second pass stage circuit 510 includes a control circuit 512. The control circuit 512 is configured to receive a first input signal from the first input 308 and a second input signal from the second input 310 and, in response, provide one or more control signals to the second pass stage circuit 510 to control an impedance of a signal path that couples the first and second follower circuits. In an example, the control circuit 512 includes a first gate drive circuit 506 and a second gate drive circuit 508.

The first gate drive circuit 506 is configured to receive the signal VIP from the first input 308 and, in response, provide a first drive signal to the first degeneration transistor MDP. The second gate drive circuit 508 is configured to receive the signal VIM from the second input 310 and, in response, provide a second drive signal to the second degeneration transistor MDM. The first and second drive signals can be the same or can be different signals. The gate drive circuits are configured to buffer the differential inputs of the third transconductance circuit 504 and, in some examples, impart an offset to the respective signals that control the degeneration transistors MDP and MDM.

To demonstrate various functions and benefits of the third transconductance circuit 504, first and second operating examples are provided. In a first operating example, the third transconductance circuit 504 can receive substantially equal magnitude signals, such as having the same polarity, at the first input 308 and the second input 310. When the input signals are substantially equal the voltage difference between the input nodes is within a threshold difference amount that controls behavior of the pass stage circuit such that the third transconductance circuit 504 exhibits the desired gain and/or bandwidth characteristics.

In an example, each input can receive a +10V signal. The first gate drive circuit 506 can be configured to receive the signal from the first input 308 and provide a corresponding first offset signal at the gate of the first degeneration transistor MDP. Similarly, the second gate drive circuit 508 can be configured to receive the signal from the second input 310 and provide a corresponding second offset signal at the gate of the second degeneration transistor MDM. In an example, the first offset signal can be 10V+Voffset and the second offset signal can be similarly or identically valued.

In an example, by selecting Voffset, resistance characteristics of the degeneration transistors can be minimized. For example, Voffset can be selected such that the degeneration transistors are caused to achieve their minimum linear region resistance. When the transistors operate in the linear region, they behave similarly to a variable resistor. For an n-channel MOSFET such as the transistors MDP and MDM, the linear region occurs when the gate-to-source voltage (Vgs) is greater than the threshold voltage (Vth) but the drain-to-source voltage (Vds) is less than the gate-to-source voltage minus the threshold voltage (Vgs-Vth). In this region, the current flowing through the MOSFET is linearly related to the drain-to-source voltage, and the device can be used to control the current flow like a resistor. The transistor impedance in the linear region is important because it affects circuit gain. In the first operating example, the linear mode impedance of the degeneration transistors MDP and MDM can be minimized by increasing the offset voltage provided by the gate drive circuits to the maximum allowed process Vgs, which in turn helps improve performance of the gain stage. Furthermore, using the first gate drive circuit 506 and the second gate drive circuit 508 to isolate the degeneration transistors MDP and MDM from the first input 308 and the second input 310, respectively, reduces capacitive loading on the inputs and helps increase the bandwidth of the third amplification stage 502.

In a second operating example, the third transconductance circuit 504 can receive unequal magnitude signals at the first input 308 and the second input 310. For example, the first input 308 can receive a +10V signal and the second input 310 can receive a different magnitude signal or can be coupled to a reference, such as 0V. In this example, the first gate drive circuit 506 can provide a first offset signal that is 10V+Voffset, and the second gate drive circuit 508 can provide a second offset signal that is 0V+Voffset. The same or different magnitude offset signals can be used by each of the gate drive circuits. In the second operating example, the degeneration transistor with the lower gate voltage (e.g., the second degeneration transistor MDM) maintains its maximum gate-source voltage Vgs. At the same time, the drain-source voltage across the transistor can increase because the source voltage at the NCM node increases, which is a function of the first gate drive circuit 506 and the operating mode (triode) of first degeneration transistor MDP. When the drain-source voltage Vds of the second degeneration transistor MDM is sufficiently large, the second degeneration transistor MDM transitions from the linear region to the saturation region. In the saturation region, the second degeneration transistor MDM operates more like a current source than a variable resistor, and the second degeneration transistor MDM is configured to “hold off” the differential voltage across its gate-to-drain (Vdg) junction. This behavior allows the circuit to tolerate high DM voltages. In other words, the transition of the second degeneration transistor MDM from the linear region to the saturation region, such as due to the change in Vds while the second gate drive circuit 508 provides a constant voltage at the gate of the second degeneration transistor MDM, helps enable the improved gain and bandwidth characteristics of the third transconductance circuit 504.

The gate drive circuits, such as the first gate drive circuit 506 or the second gate drive circuit 508, can be implemented in various ways to achieve the gain stage performance benefits described herein. The gate drive circuits can be configured to decouple gain and bandwidth performance characteristics such that high gain can be achieved without sacrificing bandwidth and high bandwidth can be achieved without sacrificing gain. The gate drive circuits can be used to help reduce capacitive loading on the gain stage inputs because the gate drive circuits are configured to buffer the inputs, or gate terminals, of the degeneration transistors. By decoupling the degeneration transistors from the gain stage inputs, capacitive loading is reduced and higher bandwidth can be realized.

The gate drive circuits can be configured to impart an offset voltage at the inputs of the degeneration transistors, which allows for minimization of the triode impedance of the devices. For example, by making the offset voltage arbitrarily large (e.g., within the limits of the process-defined maximum Vgs), the impedance of the degeneration transistors in the triode region can be made arbitrarily small, which helps improve bandwidth performance.

In an example, the small signal gain of the circuit can be influenced by the impedance characteristics of the degeneration transistors when the transistors operate in the linear region. When the gate drive circuits provide an offset, the degeneration transistor resistance can be minimized and thus small signal gain can be enhanced.

The gate drive circuits thus help afford designers more flexibility in optimizing the gain and bandwidth performance of the gain stage. In other words, applying the gate drive circuits helps enhance performance of the gain stage, bringing it closer to ideal operation by simultaneously enabling high gain, high bandwidth, and high tolerance for CM and DM operating voltages.

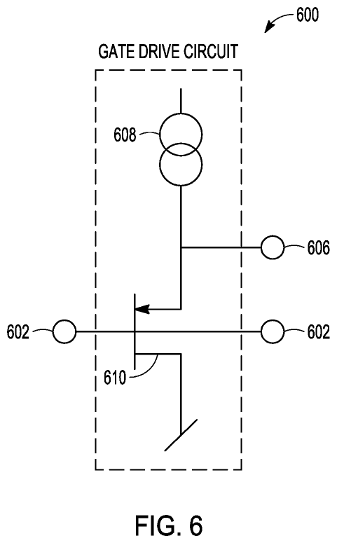

FIG. 6 illustrates generally an example of a gate drive circuit 600, such as can comprise the first gate drive circuit 506 or the second gate drive circuit 508. The gate drive circuit 600 includes a current source 608 and a first PMOS device 610. The current source 608 can be configured to provide a fixed or variable current bias signal at the source terminal of the first PMOS device 610. The gate drive circuit 600 includes an input node 602 coupled a gate terminal of the first PMOS device 610, and includes a gate drive circuit output node 606 coupled to the source terminal of the first PMOS device 610 and the current source 608. A drain terminal of the first PMOS device 610 can be coupled to a reference node or other circuitry.

In an example, the input node 602 of the gate drive circuit 600 is coupled to an input of the gain stage. For example, the input node 602 can be configured to receive one of the differential voltage signal inputs at the first input 308 or the second input 310 of the gain stage. In an example, the input node 602 can be coupled to a gate terminal, or input terminal, of an input transistor of the gain stage. That is, the input node 602 can be coupled to the first input transistor MP or to the second input transistor MM of the third transconductance circuit 504 from the example of FIG. 5.

In the example of the gate drive circuit 600 of FIG. 6, the first PMOS device 610 provides buffering and provides an offset at the source terminal or gate drive circuit output node 606 due to the Vgs characteristics of the device. Any one or more of the inputs or outputs of the gate drive circuit 600 can be separately buffered. Furthermore, other or additional voltage offset elements can be used to adjust the offset provided by the gate drive circuit 600. For example, a resistor can be added in the signal path between the current source 608 and the first PMOS device 610, or at the source of the first PMOS device 610. In another example, one or more series diode devices can be used, or a combination of one or more resistors and one or more diodes can be used.

In an example, the gate drive circuit output node 606 is coupled to a gate terminal, or input terminal, of a degeneration transistor in the gain stage. That is, the gate drive circuit output node 606 can be coupled to a gate terminal of the first degeneration transistor MDP or to a gate terminal of the second degeneration transistor MDM.

Other topologies can be similarly used to provide a drive signal to the degeneration transistors in the gain stage. That is, other circuits or controllers can be used to provide respective control signals to the inputs, or gates, of the first and second degeneration transistors MDP and MDM.

In addition to the PMOS-based gate drive circuit embodiment described in FIG. 6, various alternative topologies can achieve the same or similar function of providing a controlled offset voltage to the pass stage circuit. One alternative includes using an operational amplifier configured as a voltage follower, which offers a low-impedance output to drive the pass stage circuit. The non-inverting input of the op-amp can receive the input signal, while a voltage divider or other reference circuit connected to the inverting input establishes the offset. Additionally or alternatively, discrete transistor amplifiers, either BJTs or FETs, can be arranged in various amplifier topologies such as common-emitter or common-source to provide both gain and an offset to the input signal.

Further alternatives include level shifter circuits that adjust the voltage level of the input signal to impart the necessary offset, which can be implemented using diodes, resistor networks, or dedicated level shifter integrated circuits. Differential amplifiers can similarly serve this purpose, where one input receives the signal and the other a fixed voltage, with the output reflecting the voltage difference. Each topology presents its own set of benefits and considerations, including complexity, cost, power consumption, and precision, allowing for tailored solutions based on the specific needs of the application.

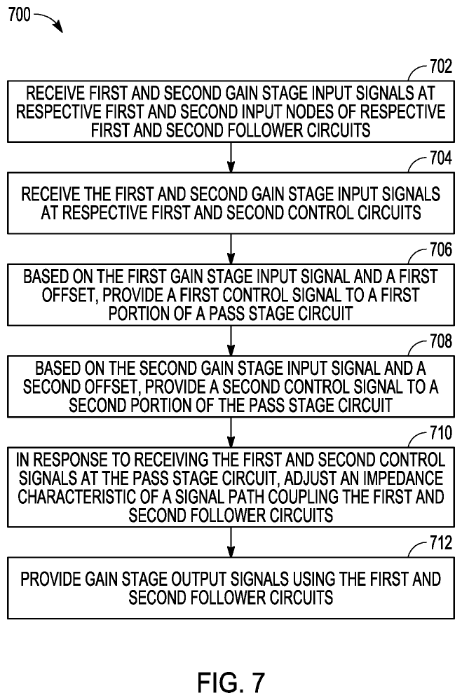

FIG. 7 illustrates generally an example of a first method 700 that includes operating a gain stage with improved gain and bandwidth characteristics. In an example, the gain stage can comprise a portion of a comparator circuit, such as can be used in a pin driver or other automated test equipment (ATE).

At operation 702, the first method 700 includes receiving first and second gain stage input signals at respective first and second input nodes of respective first and second follower circuits that comprise the gain stage. For example, operation 702 can include receiving the input signals as a differential voltage input at respective input nodes of a differential pair circuit, and the follower circuits comprise the differential pair circuit.

At operation 704, the first method 700 includes receiving the first and second gain stage input signals at a controller. In an example, the controller includes first and second control circuits that respectively receive the first and second input signals. The controller can be configured to receive the input signals and, in response, provide one or more control signals to a pass stage circuit to control an impedance of the signal path that couples the follower circuits.

At operation 706, the first method 700 includes using the first control circuit to provide a first control signal to a first portion of the pass stage circuit. The first control signal can be based on the first gain stage input signal and a first offset. At operation 708, the first method 700 includes using the second control circuit to provide a second control signal to a second portion of the pass stage circuit. The second control signal can be based on the second gain stage input signal and a second offset. In some examples, the first and second offset are same-valued or similarly valued, and in other examples, the first and second offsets can be different.

In an example, operation 706 and operation 708 can include generating the respective first and second control signals using respective control circuits or gate drive circuits. The gate drive circuits can be configured to buffer and optionally apply gain (e.g., positive or negative gain) to the input signals. The gate drive circuits can have various topologies to exhibit various buffering or gain characteristics that can depend, at least in part, on the particular application or desired flexibility of the gain stage.

At operation 710, the first method 700 includes using the first and second portions of the pass stage circuit to control an impedance characteristic of a signal path that couples the first and second follower circuits in the pass stage circuit. The impedance of the signal path can be controlled by, for example, one or more degeneration transistors provided in a signal path between source terminals of devices that comprise the first and second follower circuits. In an example, the degeneration transistors are controlled by the first and second control signals from the control circuits. That is, operation 710 can include providing the first control signal to a gate terminal of a first degeneration transistor, and can include providing the second control signal to a gate terminal of a second degeneration transistor, wherein drain terminals of the first and second degeneration transistors are coupled at an intermediate node. At operation 712, the first method 700 includes providing gain stage output signals using the first and second follower circuits.

In an example, when the first and second control signals (e.g., provided at operation 706 and operation 708) exceed a threshold voltage value, the signal path coupling the first and second follower circuits has a lower impedance characteristic and, consequently, the gain stage exhibits high bandwidth handling capability. In an example, when at least one of the first and second control signals (e.g., provided at operation 706 and operation 708) does not exceed the threshold voltage value, the signal path coupling the first and second follower circuits has a higher impedance characteristic and, consequently, the gain stage exhibits high gain capability.

Various embodiments of transconductance circuits with degeneration transistors as described herein may be implemented in any kind of system where conversion of voltage to current may be used. One example of such a system was shown in FIG. 2 where the transconductance circuit comprises part of an amplification stage, and can further include a load as illustrated in FIG. 3, FIG. 4, or FIG. 5. The transconductance circuit can optionally be followed by one or more other gain stages. In some embodiments, the transconductance circuit can comprise a portion of a comparator or an amplifier.

In some examples, the transconductance circuit can be included in a radio system, e.g., in an RF transmitter of a cellular wireless communication system. In still other examples, the transconductance circuit can be used in variable gain-amplifiers, continuous-time filters, delta-sigma modulators, or data converters.

Moreover, various embodiments of transconductance circuits with degeneration transistors can be implemented in various electronic devices. Examples of the electronic devices can include, but are not limited to, electronic products, parts of electronic products such as integrated circuits, vehicular electronics such as automotive electronics, etc. Further, the electronic devices can include unfinished or other intermediate products.

Various aspects of the present disclosure can help provide a solution to the amplifier stage gain and bandwidth-related problems identified herein, as set forth in the following Examples.
Example 1 is a gain stage circuit comprising: a first follower circuit coupled to a first input node; a second follower circuit coupled to a second input node; a pass stage circuit including an adjustable-impedance signal path that couples the first and second follower circuits; and a control circuit configured to receive a first input signal from the first input node and a second input signal from the second input node and, in response, provide a control signal to the pass stage circuit to control an impedance of the signal path that couples the first and second follower circuits.
In Example 2, the subject matter of Example 1 includes the pass stage circuit comprising a first degeneration transistor and a second degeneration transistor; wherein the control circuit is configured to provide a first control signal to a gate terminal of the first degeneration transistor and the first control signal is based on the first input signal; and wherein the control circuit is configured to provide a different second control signal to a gate terminal of the second degeneration transistor and the second control signal based on the second input signal.
In Example 3, the subject matter of Example 2 includes the first follower circuit comprising a first FET device having its gate terminal coupled to the first input node and its source terminal coupled to a source terminal of the first degeneration transistor; and wherein the second follower circuit comprises a second FET device having its gate terminal coupled to the second input node and its source terminal coupled to a source terminal of the second degeneration transistor.
In Example 4, the subject matter of Example 3 includes drain terminals of the first and second degeneration transistors coupled at an intermediate node.
In Example 5, the subject matter of Examples 2-4 includes the control circuit configured to provide the first control signal as a combination of the first input signal and a non-zero offset signal.
In Example 6, the subject matter of Example 5 includes the control circuit configured to provide the second control signal as a combination of the second input signal and the non-zero offset signal.
In Example 7, the subject matter of Examples 2-6 includes the control circuit configured to provide the first and second control signals as respective gain-adjusted versions of the first input signal and the second input signal.
In Example 8, the subject matter of Examples 2-7 includes the control circuit comprising a first gate drive circuit configured to receive the first input signal and, in response, provide a buffered first gate drive signal to the gate terminal of the first degeneration transistor; and a second gate drive circuit configured to receive the second input signal and, in response, provide a buffered second gate drive signal to the gate terminal of the second degeneration transistor.
In Example 9, the subject matter of Example 8 includes, when the first gate drive signal and the second gate drive signal are substantially equal in magnitude, the first and second degeneration transistors operate in a linear region and provide a low-impedance signal path (e.g., relatively lower than the “high-impedance” signal path in Example 10) in the pass stage circuit.
In Example 10, the subject matter of Examples 8-9 includes, wherein when the first gate drive signal and the second gate drive signal are not substantially equal in magnitude, the first and second degeneration transistors operate in a saturation region and provide a high-impedance signal path (e.g., relatively higher than the “low-impedance” signal path in Example 9) in the pass stage circuit.
In Example 11, the subject matter of Examples 1-10 includes, when respective voltage signals at the first and second input nodes are substantially equal in magnitude and polarity, the control signal is configured to control the signal path of the pass stage circuit to have a low impedance characteristic.
In Example 12, the subject matter of Examples 1-11 includes, when respective voltage signals at the first and second input nodes are not substantially equal in magnitude, the control signal is configured to control the signal path of the pass stage circuit to have a high impedance characteristic.
Example 13 is a method for controlling gain and bandwidth characteristics of a gain stage circuit in a pin driver system, the method comprising: receiving first and second gain stage input signals at respective first and second input nodes of respective first and second follower circuits; receiving the first and second gain stage input signals at respective first and second control circuits; using the first control circuit, providing a first control signal to a first portion of a pass stage circuit, wherein the first control signal is based on the first gain stage input signal and a first offset; using the second control circuit, providing a second control signal to a second portion of the pass stage circuit, wherein the second control signal is based on the second gain stage input signal and a second offset; in response to receiving the first and second control signals at the pass stage circuit, adjusting an impedance characteristic of a signal path coupling the first and second follower circuits; and providing gain stage output signals using the first and second follower circuits.
In Example 14, the subject matter of Example 13 includes the first and second offsets being same-valued voltage offset signals.
In Example 15, the subject matter of Examples 13-14 includes, when the first and second control signals exceed a threshold voltage value, the signal path coupling the first and second follower circuits has a lower impedance characteristic and the gain stage exhibits high BW handling capability, and wherein when at least one of the first and second control signals does not exceed the threshold voltage value, the signal path coupling the first and second follower circuits has a higher impedance characteristic and the gain stage exhibits high gain capability.
In Example 16, the subject matter of Examples 13-15 includes providing the first control signal to the pass stage circuit including providing the first control signal to a gate terminal of a first degeneration transistor, and wherein providing the second control signal to the pass stage circuit includes providing the second control signal to a gate terminal of a second degeneration transistor, wherein drain terminals of the first and second degeneration transistors are coupled at an intermediate node.
In Example 17, the subject matter of Examples 13-16 includes receiving the first and second gain stage input signals at the respective first and second control circuits including receiving the first and second gain stage input signals at respective gate terminals of respective PMOS devices that comprise the control circuits.
In Example 18, the subject matter of Examples 13-17 includes, at the first control circuit: receiving the first gain stage input signal; providing a buffered copy of the first gain stage input signal to a first input of a summing amplifier; providing an offset signal to a second input of the summing amplifier; and providing the first control signal to the first portion of the pass stage circuit from an output of the summing amplifier.
Example 19 is a system comprising: a first portion of a transconductance circuit including: a first gate drive circuit configured to provide a first gate drive signal, based on a first input signal, to a pass stage circuit; a first degeneration transistor of the pass stage circuit configured to receive the first gate drive signal; and a first input transistor configured to provide a first output current at a first output node, the first input transistor coupled to the first degeneration transistor; and a second portion of the transconductance circuit including: a second gate drive circuit configured to provide a second gate drive signal, based on a second input signal, to the pass stage circuit; a second degeneration transistor of the pass stage circuit configured to receive the second gate drive signal; and a second input transistor configured to provide a second output current at a second output node, the second input transistor coupled to the second degeneration transistor.
In Example 20, the subject matter of Example 19 includes drain terminals of the first and second degeneration transistors coupled at an intermediate node.
In Example 21, the subject matter of Examples 19-20 includes a gate terminal of the first input transistor is configured to receive the first input signal to the transconductance circuit and a gate terminal of the second input transistor is configured to receive the second input signal to the transconductance circuit.
Example 22 is an apparatus comprising means to implement of any of Examples 1-21.
Example 23 is a system to implement of any of Examples 1-21.

Each of these non-limiting Examples can stand on its own, or can be combined in various permutations or combinations with one or more of the other Examples or features discussed elsewhere herein.

This detailed description includes references to the accompanying drawings, which form a part of the detailed description. The drawings show, by way of illustration, specific embodiments in which the invention can be practiced. These embodiments are also referred to herein as “examples.” Such examples can include elements in addition to those shown or described. However, the present inventors also contemplate examples in which only those elements shown or described are provided. The present inventors contemplate examples using any combination or permutation of those elements shown or described (or one or more aspects thereof), either with respect to a particular example (or one or more aspects thereof), or with respect to other examples (or one or more aspects thereof) shown or described herein.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.”

In the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

Method examples described herein can be machine or computer-implemented at least in part. Some examples can include a computer-readable medium or machine-readable medium encoded with instructions operable to configure an electronic device to perform methods or circuit operations or circuit configuration instructions as described in the above examples. An implementation of such methods can include code, such as microcode, assembly language code, a higher-level language code, or the like. Such code can include computer readable instructions for performing various methods. The code may form portions of computer program products. Further, in an example, the code can be tangibly stored on one or more volatile, non-transitory, or non-volatile tangible computer-readable media, such as during execution or at other times. Examples of these tangible computer-readable media can include, but are not limited to, hard disks, removable magnetic disks, removable optical disks (e.g., compact disks and digital video disks), magnetic cassettes, memory cards or sticks, random access memories (RAMs), read only memories (ROMs), and the like.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description as examples or embodiments, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

What is claimed is:

1. A gain stage circuit comprising:
a first follower circuit coupled to a first input node;
a second follower circuit coupled to a second input node;
a pass stage circuit including an adjustable-impedance signal path that couples the first and second follower circuits; and
a control circuit configured to receive a first input signal from the first input node and a second input signal from the second input node and, in response, provide a control signal to the pass stage circuit to control an impedance of the signal path that couples the first and second follower circuits.

2. The gain stage circuit of claim 1, wherein the pass stage circuit comprises a first degeneration transistor and a second degeneration transistor;
wherein the control circuit is configured to provide a first control signal to a gate terminal of the first degeneration transistor and the first control signal is based on the first input signal; and
wherein the control circuit is configured to provide a different second control signal to a gate terminal of the second degeneration transistor and the second control signal based on the second input signal.

3. The gain stage circuit of claim 2,
wherein the first follower circuit comprises a first FET device having its gate terminal coupled to the first input node and its source terminal coupled to a source terminal of the first degeneration transistor; and
wherein the second follower circuit comprises a second FET device having its gate terminal coupled to the second input node and its source terminal coupled to a source terminal of the second degeneration transistor.

4. The gain stage circuit of claim 3, wherein drain terminals of the first and second degeneration transistors are coupled at an intermediate node.

5. The gain stage circuit of claim 2, wherein the control circuit is configured to provide the first control signal as a combination of the first input signal and a non-zero offset signal.

6. The gain stage circuit of claim 5, wherein the control circuit is configured to provide the second control signal as a combination of the second input signal and the non-zero offset signal.

7. The gain stage circuit of claim 2, wherein the control circuit is configured to provide the first and second control signals as respective gain-adjusted versions of the first input signal and the second input signal.

8. The gain stage circuit of claim 2, wherein the control circuit comprises:
a first gate drive circuit configured to receive the first input signal and, in response, provide a buffered first gate drive signal to the gate terminal of the first degeneration transistor; and
a second gate drive circuit configured to receive the second input signal and, in response, provide a buffered second gate drive signal to the gate terminal of the second degeneration transistor.

9. The gain stage circuit of claim 8, wherein when the first gate drive signal and the second gate drive signal are substantially equal in magnitude, the first and second degeneration transistors operate in a linear region and provide the signal path in the pass stage circuit.

10. The gain stage circuit of claim 8, wherein when the first gate drive signal and the second gate drive signal are not substantially equal in magnitude, the first and second degeneration transistors operate in a saturation region and inhibit signal transmission through the pass stage circuit.

11. The gain stage circuit of claim 1, wherein when respective voltage signals at the first and second input nodes are substantially equal in magnitude and polarity, the control signal is configured to control the signal path of the pass stage circuit to have a low impedance characteristic, and when respective voltage signals at the first and second input nodes are not substantially equal in magnitude, the control signal is configured to control the signal path of the pass stage circuit to have a high impedance characteristic.

12. A method for controlling gain and bandwidth characteristics of a gain stage circuit in a pin driver system, the method comprising:
receiving first and second gain stage input signals at respective first and second input nodes of respective first and second follower circuits;
receiving the first and second gain stage input signals at respective first and second control circuits;
using the first control circuit, providing a first control signal to a first portion of a pass stage circuit, wherein the first control signal is based on the first gain stage input signal and a first offset;
using the second control circuit, providing a second control signal to a second portion of the pass stage circuit, wherein the second control signal is based on the second gain stage input signal and a second offset;
in response to receiving the first and second control signals at the pass stage circuit, adjusting an impedance characteristic of a signal path coupling the first and second follower circuits; and
providing gain stage output signals using the first and second follower circuits.

13. The method of claim 12, wherein the first and second offsets are same-valued voltage offset signals.

14. The method of claim 12, wherein when the first and second control signals exceed a threshold voltage value, the signal path coupling the first and second follower circuits has a lower impedance characteristic, and wherein when at least one of the first and second control signals does not exceed the threshold voltage value, the signal path coupling the first and second follower circuits has a higher impedance characteristic.

15. The method of claim 12, wherein providing the first control signal to the pass stage circuit includes providing the first control signal to a gate terminal of a first degeneration transistor, and wherein providing the second control signal to the pass stage circuit includes providing the second control signal to a gate terminal of a second degeneration transistor, wherein drain terminals of the first and second degeneration transistors are coupled at an intermediate node.

16. The method of claim 12, wherein receiving the first and second gain stage input signals at the respective first and second control circuits includes receiving the first and second gain stage input signals at respective gate terminals of respective PMOS devices that comprise the control circuits.

17. The method of claim 12, comprising, at the first control circuit:
receiving the first gain stage input signal;
providing a buffered copy of the first gain stage input signal to a first input of a summing amplifier;
providing an offset signal to a second input of the summing amplifier; and
providing the first control signal to the first portion of the pass stage circuit from an output of the summing amplifier.

18. A system comprising:
a first portion of a transconductance circuit including:
a first gate drive circuit configured to provide a first gate drive signal, based on a first input signal, to a pass stage circuit;
a first degeneration transistor of the pass stage circuit configured to receive the first gate drive signal; and
a first input transistor configured to provide a first output current at a first output node, the first input transistor coupled to the first degeneration transistor; and
a second portion of the transconductance circuit including:
a second gate drive circuit configured to provide a second gate drive signal, based on a second input signal, to the pass stage circuit;
a second degeneration transistor of the pass stage circuit configured to receive the second gate drive signal; and
a second input transistor configured to provide a second output current at a second output node, the second input transistor coupled to the second degeneration transistor.

19. The system of claim 18, wherein drain terminals of the first and second degeneration transistors are coupled at an intermediate node.

20. The system of claim 18, wherein a gate terminal of the first input transistor is configured to receive the first input signal to the transconductance circuit and a gate terminal of the second input transistor is configured to receive the second input signal to the transconductance circuit.
